(19) United States
(12) Patent Application Publication
(10) Pub. No.: US 2013/0201644 A1
(43) Pub. Date: Aug. 8, 2013

(54) CHIP CARD REMOVING DEVICE AND ELECTRONIC DEVICE USING THE SAME

(71) Applicants: MIN-SHENG WANG, Tu-Cheng (TW); YU-CHIA HUANG, Tu-Cheng (TW)

(72) Inventors: MIN-SHENG WANG, Tu-Cheng (TW); YU-CHIA HUANG, Tu-Cheng (TW)

(21) Appl. No.: 13/653,678

(22) Filed: Oct. 17, 2012

(30) Foreign Application Priority Data
Feb. 6, 2012 (TW) 101103702

(51) Int. Cl. H05K 5/00

(52) U.S. Cl. 361/754

(57) ABSTRACT

A chip card removing device used for removing a chip card from an electronic device includes a housing and a chip card tray slidably mounted in the housing. The chip card tray includes a main body, and a stopping portion protruding from one end of the main body. The stopping portion and the main body form a receiving space for receiving the chip card. The stopping portion resists against the chip card. When the chip card tray is slid out of the housing, the chip card is brought with it to expose the chip card out of the housing. An electronic device using the chip card removing device is also described.

### BACKGROUND

1. Technical Field

The present disclosure relates to chip card removing devices and electronic devices using the chip card removing device.

2. Description of Related Art

Chip cards, such as subscriber identity module (SIM) cards, are broadly applied in portable electronic devices such as mobile phones, and personal digital assistants (PDA). Sometimes, the SIM cards must be taken out from the electronic devices. However, the known SIM cards are commonly directly inserted in the electronic device. Since SIM cards are very small and thin, it is difficult for users to pull out the SIM cards manually from the electronic devices.

Therefore, there is room for improvement within the art.

### BRIEF DESCRIPTION OF THE DRAWINGS

Many aspects of the disclosure can be better understood with reference to the following figures. The components in the figures are not necessarily drawn to scale, the emphasis instead being placed upon clearly illustrating the principles of the disclosure. Moreover, in the drawings, like reference numerals designate corresponding parts throughout the several views.

FIG. 1 is an exploded view of an exemplary embodiment of an electronic device.

FIG. 2 is another exploded view of the electronic device shown in FIG. 1.

FIG. 3 is an enlarged view of the portion III shown in FIG. 2.

FIG. 4 is an assembled view of the electronic device shown in FIG. 1.

FIG. 5 is a schematic view of a chip card being mounted in the electronic device of FIG. 4.

FIG. 6 is a schematic view of the chip card being taken out from the electronic device of FIG. 4.

### DETAILED DESCRIPTION

A chip card removing device according to an exemplary embodiment may be applied to mobile phones, and PDAs. The exemplary embodiment illustrates the chip card removing device and a mobile phone as the electronic device.

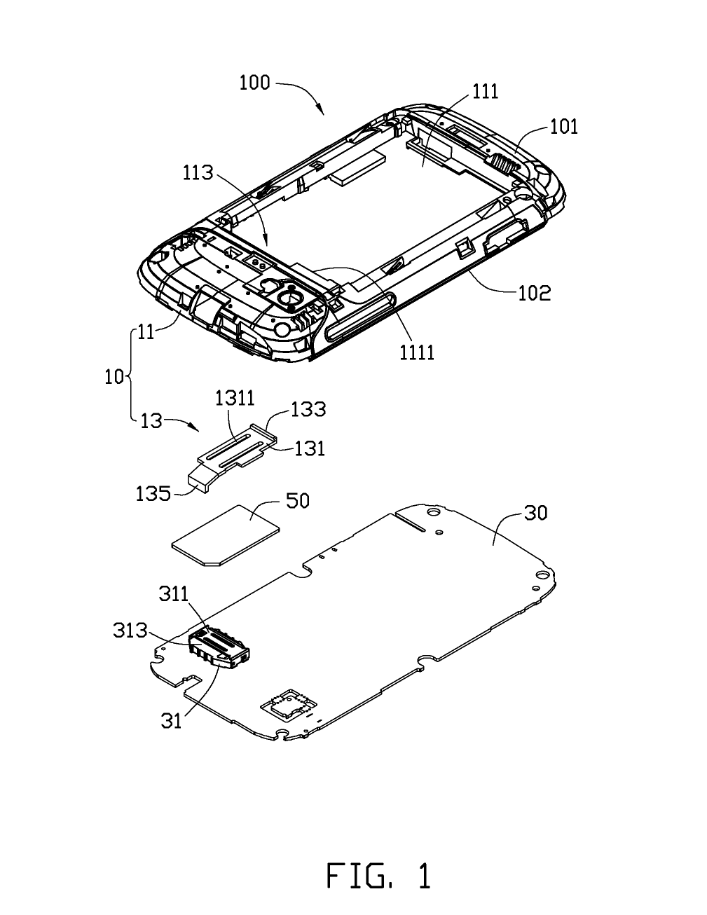

Referring to FIG. 1, an electronic device 100 includes a chip card removing device 10, a circuit board 30, and a chip card 50 mounted on and electrically connected with the circuit board 30. The chip card removing device 10 is for taking the chip card 50 out of the electronic device 100. In the embodiment, the chip card 50 is a SIM card.

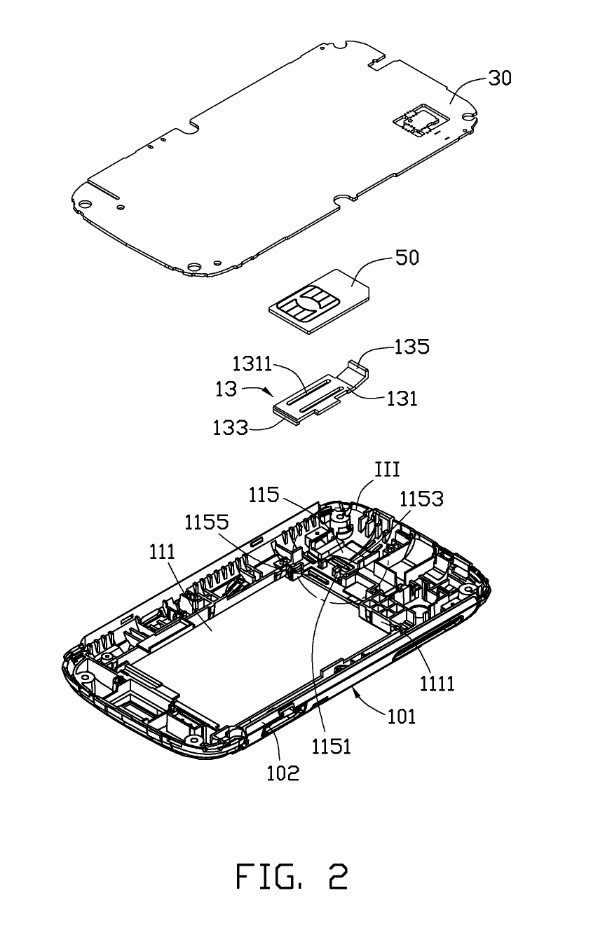

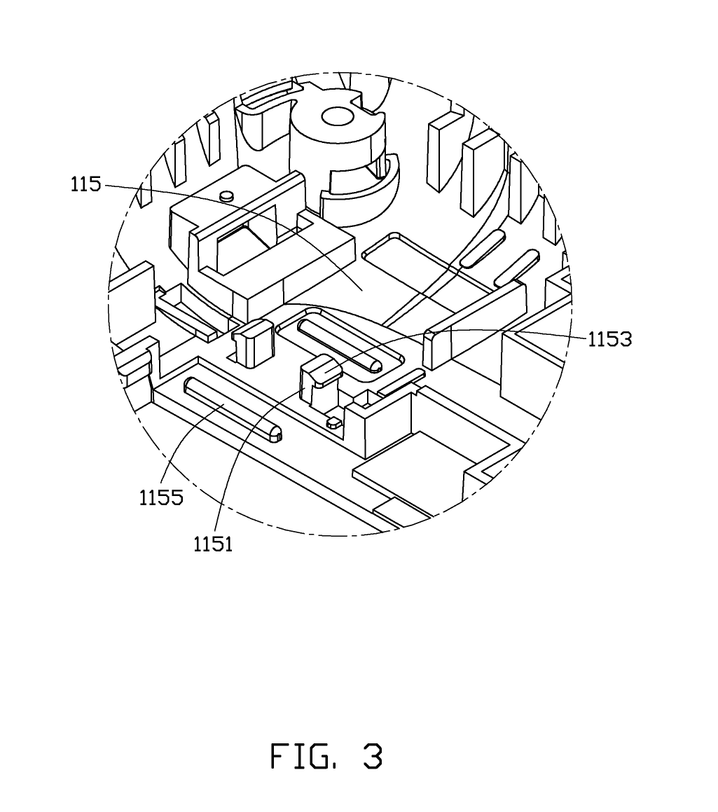

Referring to FIGS. 2 and 3 also, the chip card removing device 10 includes a housing 11 and a chip card tray 13 detachably mounted in the housing 11. The housing 11 may be a portion of the electronic device 100. The housing 11 includes a first surface 101 and a second surface 102 opposite to the first surface 101. The first surface 101 defines a receiving cavity 111 which receives a battery (not shown) for the electronic device 100. The receiving cavity 111 has a sidewall 1111. The sidewall 1111 defines a cutout 113.

The second surface 102 defines a receiving portion 115 which communicates with the cutout 113 of the sidewall 1111. The outline of the receiving portion 115 matches the chip card tray 13, and is for receiving the chip card tray 13.

The receiving portion 115 defines at least one fastening element 1151 protruding from the surface of the receiving portion 115. In the embodiment, there are two parallel fastening elements 1151 which are arranged opposite to each other. Each fastening element 1151 defines a latching portion 1153. The two latching portions 1153 face away from each other. The latching portions 1153 latch with the chip card tray 13 and prevent the chip card tray 13 from detaching from the receiving portion 115.

The receiving portion 115 further defines at least one rib 1155 protruding from the surface of the receiving portion 115. In the embodiment, there are two parallel ribs 1155 which are arranged opposite to each other. The two fastening elements 1151 are positioned between the two ribs 1155. The ribs 1155 support the chip card tray 13 when the chip card tray 13 is moved in or out of the receiving portion 115.

The chip card tray 13 includes a main body 131, an operating portion 133, and a stopping portion 135.

The main body 131 defines at least one through sliding slot 1311. In the embodiment, there are two parallel sliding slots 1311. The sliding slots 1311 mate with the fastening elements 1151, allowing the fastening elements 1151 to pass through the sliding slots 1311 and the latching portions 1153 to latch over the edges of the sliding slots 1311, thus mounting the main body 131/chip card tray 13 on the housing 11, so that the chip card tray 13 is limited in sliding in or out of the receiving portion 115 along the fastening elements 1151.

The operating portion 133 protrudes from a surface adjacent to one end of the main body 131. The operating portion 133 is for users to pull the chip card tray 13 out of the receiving portion 115 or push the chip card tray 13 into the receiving portion 115. The stopping portion 135 extends from the other end of the main body 131 and defines a bent portion towards the other surface of the main body 131. The stopping portion 135 and the main body 131 cooperatively form a receiving space for receiving the chip card. The stopping portion 135 resists the chip card 50 when the chip card 50 is inserted into the receiving space/receiving portion 115 of the housing 11 and positioned on the main body 131.

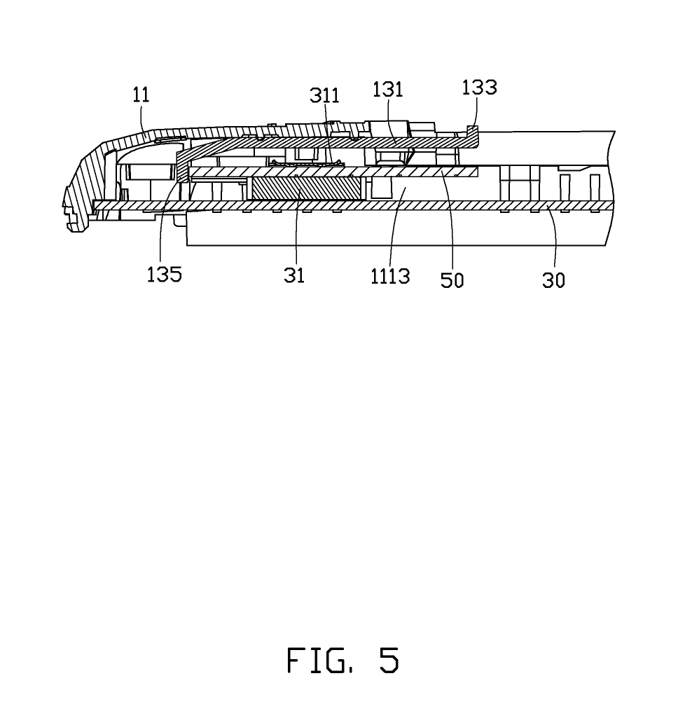

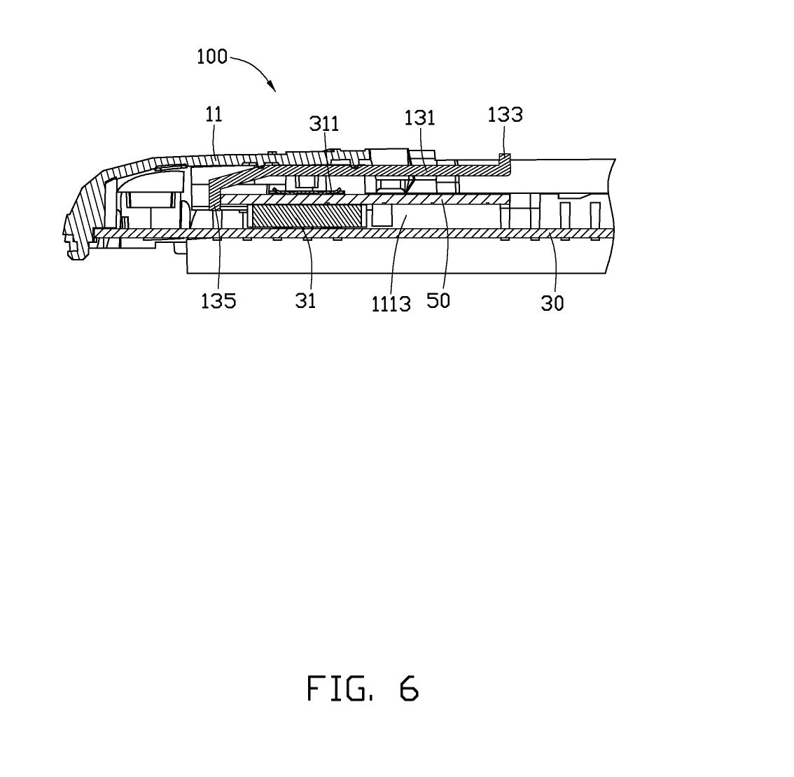

The circuit board 30 is mounted on the second surface 102 of the housing 11 by screws and covers the receiving cavity 111. When the circuit board 30 is mounted on the housing 11, a chip card receiving space 1113 (referring to FIGS. 5 and 6) is defined by the circuit board 30 and the chip card tray 13 for receiving the chip card 50. The circuit board 30 includes an electrical connector 31 towards the chip card receiving space 1113. The electrical connector 31 defines a connecting terminal 311 and a space 313 (referring to FIGS. 1, 5, and 6). The electrical connector 31 electrically connects the chip card 50 to the circuit board 30.

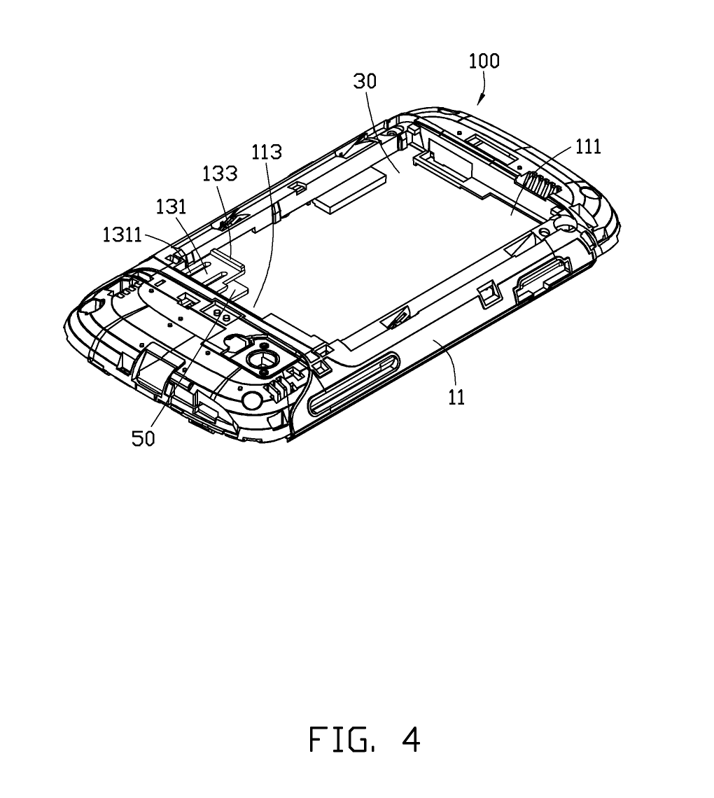

Referring to FIGS. 4 and 5, when assembling the device housing 100, the chip card removing device 10 is first assembled. The main body 131 is pressed to make the fastening elements 1151 pass through the sliding slots 1311 to mount the chip card tray 13 on the fastening elements 1151. At this time, the latching portions 1153 latch over the edges of the sliding slots 1311, and the surface of the main body 131 defining the operating portion 133 faces the receiving portion 115. Then the circuit board 30 is mounted by screws on the second surface 102 of the housing 11, and the connecting terminal 311 faces towards the chip card receiving space 1113 and the chip card tray 13. The chip card 50 is then inserted in the electronic device 100. Specifically, one end of the chip card 50 is urged into the chip card receiving space 1113 from the cutout 113 of the sidewall 1111 and then the chip card 50 passes through the space 313 of the electronic connector 31 until the chip card 50 butts against the stopping portion 135 of the chip card tray 13. At this time, the connecting terminal 311 is electrically connecting the chip card 50 to the circuit board 30.

Referring to FIG. 6, when taking out the chip card 50, the operating portion 133 is pulled by a fingernail to make the chip card tray 13 move along the fastening elements 1151 of the receiving portion 115. The resisting surface of the stopping portion 135 brings the chip card 50 along with the chip card tray 13. When the operating portion 133 is further pulled, the chip card 50 moves out from the cutout 113 of the sidewall 1111 until the sliding slots 1311 reach their limit against the fastening portions 1151. As such, the chip card 50 is wholly exposed from the electronic device 100.

The electronic device 100 of the exemplary embodiment includes the chip card removing device 10 defining the chip card tray 13. The chip card 50 can be taken out from the electronic device 100 merely by pulling the operating portion 133 of the chip card tray 13, which is a very convenient and rapid way to take out the chip card 50.

It is believed that the exemplary embodiment and its advantages will be understood from the foregoing description, and it will be apparent that various changes may be made thereto without departing from the spirit and scope of the disclosure or sacrificing all of its advantages, the examples hereinbefore described merely being preferred or exemplary embodiment of the disclosure.

What is claimed is:

1. A chip card removing device used for removing a chip card from an electronic device, the chip card removing device comprising:
a housing; and
a chip card tray slidably mounted in the housing;
the chip card tray comprising:
a main body; and
a stopping portion protruding from one end of the main body , the stopping portion and the main body cooperatively forming a receiving space for receiving the chip card therein, the stopping portion configured for resisting against the chip card;
wherein with the chip card tray sliding out of the housing, the stopping portion drives the chip card to move along with the main body to expose the chip card out of the housing.

2. The chip card removing device as claimed in claim 1, wherein the chip card tray further comprises an operating portion protruding from another end of the main body for use in moving the chip card tray.

3. The chip card removing device as claimed in claim 1, wherein the stopping portion defines a bent portion, the bent portion resists against the chip card.

4. The chip card removing device as claimed in claim 1, wherein a surface of the housing defines a receiving portion, the receiving portion defining at least one fastening element protruding from the surface of the receiving portion, the main body defines at least one through sliding slot mating with the fastening element, the fastening element passes through the sliding slot to slidably mount the main body of the chip card tray in the housing, and the chip card tray is received in the receiving portion and slides in or out of the receiving portion along the fastening element.

5. The chip card removing device as claimed in claim 4, wherein the at least one fastening element comprises two fastening elements, the two fastening elements are arranged in parallel, each fastening element defines a latching portion, the two latching portions are opposite to each other, the latching portions latch with the chip card tray and prevent the chip card tray from detaching from the receiving portion.

6. The chip card removing device as claimed in claim 5, wherein the at least one through sliding slot comprises two sliding slots, the two sliding slots are arranged in parallel, the latching portions latch the edges of the two sliding slots to prevent the chip card tray from detaching from the receiving portion.

7. The chip card removing device as claimed in claim 5, wherein the receiving portion further defines at least one rib protruding from the surface of the receiving portion to support the chip card tray when the chip card tray slides in or out of the receiving portion.

8. The chip card removing device as claimed in claim 7, wherein the at least one rib comprises two ribs, the two ribs are arranged in parallel, the two fastening elements position between the two ribs.

9. An electronic device, comprising:
a circuit board; and
a chip card removing device for taking out chip card from the electronic device, the chip card removing device comprising:
a housing; and
a chip card tray slidably mounted in the housing;
the chip card tray comprising:
a main body removably mounted in the housing; and
a stopping portion protruding from one end of the main body, the stopping portion configured for resisting against the chip card;
the circuit board being mounted on the housing and forming a chip card receiving space with the chip card tray, the chip card being received in the chip card receiving space, when the chip card tray is slid out of the housing, the stopping portion drives the chip card to move with the main body to expose the chip card out of the housing.

10. The electronic device as claimed in claim 9, wherein the chip card tray further comprises an operating portion protruding from another end of the main body for use in moving the chip card tray.

11. The electronic device as claimed in claim 9, wherein the stopping portion defines a bent portion, the bent portion resists against the chip card.

12. The electronic device as claimed in claim 9, wherein the housing comprises a first surface and a second surface opposite to the first surface, the circuit board is mounted on the second surface.

13. The electronic device as claimed in claim 12, wherein the first surface defines a receiving cavity, the receiving cavity has a sidewall, the sidewall defines a cutout, the second surface defines a receiving portion, the main body and the stopping portion of the chip card tray is received in the receiving portion, the receiving portion communicates with the cutout, the chip card is inserted in the chip card receiving space from the cutout to resist against the stopping portion of the chip card tray.

14. The electronic device as claimed in claim 13, wherein the circuit board comprises an electrical connector towards the chip card receiving space, the electrical connector defines a connecting terminal and a space, the chip card is inserted to the chip card receiving space and passes through the space and electrically connects the connecting terminal

15. The electronic device as claimed in claim 13, wherein the receiving portion defines at least one fastening element protruding from the surface of the receiving portion, the main body defines at least one through sliding slot mating with the fastening element, the fastening element passes through the sliding slot to slidably mount the main body of the chip card tray in the housing, and the main body slides in or out of the receiving portion along the fastening element.

16. The electronic device as claimed in claim 15, wherein the at least one fastening element comprises two fastening elements, the two fastening elements are arranged in parallel, each fastening element defines a latching portion, the two latching portions are opposite to each other, the latching portions latch with the chip card tray and prevent the chip card tray from detaching from the receiving portion.

17. The electronic device as claimed in claim 16, wherein the at least one through sliding slot comprises two sliding slots, the two sliding slots are arranged in parallel, the latching portions latch over the edges of the two sliding slots to prevent the chip card tray from detaching from the receiving portion.

18. The electronic device as claimed in claim 15, wherein the receiving portion further defines at least one rib protruding from the surface of the receiving portion to support the chip card tray when the chip card tray is slid in or out of the receiving portion.

19. The electronic device as claimed in claim 18, wherein the at least one rib comprises two ribs, the two ribs are arranged in parallel, the two fastening elements are positioned between the two ribs.

20. A chip card removing device for taking out chip card from an electronic device, the chip card removing device comprising:
a housing; and
a chip card tray mounted in the housing;
the chip card tray comprising:
a main body removably mounted in the housing;
an operating portion protruding from a surface adjacent to one end of the main body; and
a stopping portion, for resisting against the chip card, extending along the other end of the main body and defining a bent portion towards the other surface of the main body;
when operating the operating portion, the main body is slid to make the stopping portion drive the chip card to move with the main body to expose the chip card out of the housing.
